(19) United States
(12) Patent Application Publication
(10) Pub. No.: US 2014/0027038 A1
(43) Pub. Date: Jan. 30, 2014

(54) METHOD FOR MANUFACTURING CONDUCTIVE FIBER AND/OR FABRICS, CONDUCTIVE FIBER AND/OR FABRIC, AND METHOD FOR MANUFACTURING CIRCUIT BOARD

(71) Applicant: Korea Institute of Machinery & Materials, Daejeon (KR)

(72) Inventor: Hye Moon LEE, Changwon-si (KR)

(73) Assignee: KOREA INSTITUTE OF MACHINERY & MATERIALS, Daejeon (KR)

(21) Appl. No.: 14/042,867

(22) Filed: Oct. 1, 2013

Related U.S. Application Data
(63) Continuation of application No. PCT/KR2012/007606, filed on Sep. 21, 2012.

(30) Foreign Application Priority Data
Apr. 16, 2012 (KR) 10-2012-0039275

(51) Int. Cl. H01B 13/30; H05K 3/10

(52) U.S. Cl. CPC H01B 13/30; H05K 3/103
USPC 156/60; 427/123; 29/428

(57) ABSTRACT

A method for manufacturing a conductive fiber and/or fabric, a conductive fiber and/or fabric, and a method for manufacturing a circuit board are provided, the method for manufacturing a conductive fiber and/or fabric including: preparing a composition including a solvent and a metal precursor; impregnating a fiber and/or fabric with the composition; and reducing the metal precursor in the fiber and/or fabric impregnated with the composition into a metal to obtain a conductive fiber and/or fabric, wherein the composition includes 50 to 99 wt % of the solvent and 1 to 50 wt % of the metal precursor.

### CROSS-REFERENCE TO RELATED APPLICATION

This application is a continuation application of International Application No. PCT/KR2012/007606 filed on Sep. 21, 2012, which claims priority to Korean Patent Application No. 10-2012-0039275, filed on Apr. 16, 2012, the entire contents of which are incorporated herein by reference.

### BACKGROUND OF THE INVENTION

(a) Field of the Invention

The present invention relates to a method for manufacturing a conductive fiber and/or fabric, a conductive fiber and/or fabric, and a method for manufacturing a circuit board.

(b) Description of the Related Art

Smart wear is a new product that is designed to use a digital function at any time anywhere by applying a new technology of signal-transmitting fiber to a textile fashion product and embedding various digital devices therein. In other words, the smart wear is new clothing that retains features of textile materials or clothing and has necessary digital functions embedded in the textile materials and clothing.

For this reason, the smart wear needs to exhibit feeling and physical properties that are nearly the same as those of general fabrics, and transmit a digital signal. Therefore, “smart wear” may be the generic term for a new concept of clothing in which high-function material properties of textiles or clothing itself of sensing external stimuli and allowing self-reaction and digitalized properties that textiles or clothing itself does not have are combined with each other.

Currently, the smart wear that began to be developed for military purposes from the mid-1990s has been most actively developed in a clothing field, a medical field, and the like. Particularly, smart wear materials using a printing electronic technology may be variously used in military textile products with a wearable computer. In the case where the printing electronic technology is used in the smart wear materials in an interconnection manner of connecting a conductive fiber and/or fiber having clothing features and electrical features and various kinds of parts to each other, it is possible to design a fabric-based electronic circuit and thus the smart wear has a high value of application.

For example, the application of the printing electronic technology to a military uniform may lead to a possibility of weight reduction and volume decrease, and thus it is possible to develop a military uniform with a wound healing function, a communication function, and the like in one body. The development of the present method is urgently needed since soldiers should carry equipment exceeding 45 kg when they are fully armed even in modern warfare with the latest technology.

In order to manufacture this smart wear, a technology of combining several factors for a Body Area Network (BAN) is required.

For achieving this, several methods are suggested, and for example, a fabric is formed of an insulated wire, a metal yarn having electrical conductivity, or an insulating yarn. According to this method, electrical conductivity is determined depending on the number and size of conductive metal yarns or yarns.

Among the proposed methods, in the case of a method of attaching the insulating wire to the final wear, a process of attachment/insulation of the insulating wire is further conducted in the final procedure, resultantly causing an increase in cost, and the insulating wire in the fiber is broken due to continuous use of a wearer, failing to exhibit inherent functions thereof.

More specifically, PCT Publication No. WO2004/107831 proposed an electrically conductive fabric capable of selectively having elasticity by allowing non-conductive fibers to impart elasticity to the fabric during interweaving of the conductive fibers and non-conductive fibers.

In addition, PCT Publication No. WO2003/095729 proposed a multilayer woven article having an electronic function woven therein including: warp and weft yarns interwoven in a multilayer weave having plural layers defining at least one cavity therebetween; at least one electrically conductive yarn disposed in the warp and/or in the weft and having a portion thereof in one of the plural layers defining the at least one cavity; and a circuit carrier disposed in the cavity and electrically contacting at least one electrically conductive yarn.

The above information disclosed in this Background section is only for enhancement of understanding of the background of the invention, and therefore it may contain information that does not form the prior art that is already known in this country to a person of ordinary skill in the art.

### SUMMARY OF THE INVENTION

The present invention has been made in an effort to provide an electrical or electronic circuit board having advantages of having excellent availability by providing an effective method for manufacturing a conductive fiber. Further, the present invention has been made in an effort to provide a fiber electrode and a fiber type of electric circuit board having advantages of having excellent availability and being applied to wearable electronic devices such as a wearable computer and a human-protectable device. In addition, the present invention has been made in an effort to provide a fiber electrode and a fiber type of electric circuit board having advantages of being applied to various fields such as fabrics such as clothing goods, non-woven fabrics such as papers, interior and exterior building materials, mechanical materials for a vehicle and the like, medical materials, and the like.

An exemplary embodiment of the present invention provides a method for manufacturing a conductive fiber and/or fabric, the method including: preparing a composition including a solvent and a metal precursor; impregnating a fiber and/or fabric with the composition; and reducing or decomposing the metal precursor in the fiber and/or fabric impregnated with the composition into a metal to obtain a conductive fiber and/or fabric.

Here, in the reducing or decomposition of the metal precursor in the fiber and/or fabric impregnated with the composition into the metal to obtain the conductive fiber and/or fabric, the fiber and/or fabric impregnated with the composition may be maintained at room temperature for a predetermined time.

More specifically, in the impregnating of the fiber and/or fabric with the composition, and the reducing or decomposition of the metal precursor in the fiber and/or fabric impregnated with the composition into the metal to obtain the conductive fiber and/or fabric, the fiber and/or fabric may be immersed in the composition and then maintained at room temperature for a predetermined time.

Here, in the reducing or decomposition of the metal precursor in the fiber and/or fabric impregnated with the composition into the metal to obtain the conductive fiber and/or fabric, the fiber and/or fabric impregnated with the composition may be subjected to heat treatment.

The heat treatment may be performed at a temperature of 150° C. or lower.

The method may further include, before the impregnating of the fiber and/or fabric with the composition, treating the fiber and/or fabric with a catalyst or a reducing agent.

The metal precursor may be a metal chloride, a metal hydride, a metal hydroxide, a metal sulfide, a metal nitrate, a metal nitride, a metal halide, a metal alkyl compound, a metal aryl compound, a complex thereof, or a combination thereof.

The metal precursor may be a compound in which organic or inorganic ligands are independently or complexly linked to a metal hydride.

The organic and inorganic ligands may each independently be selected from amines, phosphines, ethers, sulfides, thiols, and combinations thereof.

The metal precursor may be represented by Chemical Formula 1 and/or Chemical Formula 2 below.

R¹ₓM_{w}R²_{z} [Chemical Formula 1]

[R¹ᵥA]ₓM_{w}R²_{z} [Chemical Formula 2]

In Chemical Formula 1 and Chemical Formula 2, A is at least one of VA-group elements or VIA-group elements; x is any one integer of 0 to 3; y is any one integer of 1 to 3; z is any one integer of 1 to 8; w is any one integer of 1 to 5; and R¹ and R² each are independently H, a C₁-C₂₀ alkyl, a C₂-C₂₀ alkenyl, a C₂-C₂₀ alkynyl, a C₃-C₁₂₀ cycloalkyl, a C₄-C₁₂₀ cycloalkenyl, a C₆-C₁₀₀ aryl, or a C₇-C₁₀₀ aralkyl. M may be aluminum (Al), lithium (Li), sodium (Na), potassium (K), rubidium (Rb), cesium (Cs), beryllium (Be), magnesium (Mg), calcium (Ca), strontium (Sr), barium (Ba), titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), gallium (Ga), indium (In), thallium (Tl), silicon (Si), germanium (Ge), tin (Sn), lead (Pb), phosphor (P), arsenic (As), antimony (Sb), bismuth (Bi), or a combination thereof.

The metal precursor may be a type of metal inorganic salt, a negative ion of the metal inorganic salt being a hydroxide ion, an acetate ion, a propionate ion, an acetylacetonate ion, a 2,2,6,6-tetramethyl-3,5-heptanedionate ion, a methoxide ion, a sec-butoxide ion, a t-butoxide ion, an n-propoxide ion, an i-propoxide ion, an ethoxide ion, a phosphate ion, an alkylphosphate ion, a nitrate ion, a perchlorate ion, a sulfate ion, an alkylsulfonate ion, a phenoxide ion, a bromide ion, an iodide ion, a chloride ion, a nitride ion, a nitrate ion, a sulfide ion, a sulfate ion, or a combination thereof.

The metal of the metal precursor may be aluminum (Al), lithium (Li), sodium (Na), potassium (K), rubidium (Rb), cesium (Cs), beryllium (Be), magnesium (Mg), calcium (Ca), strontium (Sr), barium (Ba), titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), gallium (Ga), indium (In), thallium (Tl), silicon (Si), germanium (Ge), tin (Sn), lead (Pb), phosphor (P), arsenic (As), antimony (Sb), bismuth (Bi), or a combination thereof.

The metal precursor may be AlH₃, OAlH₃(C₂H₅)₂, OAlH₃(C₃H₇)₂, OAlH₃(C₄H₉)₂, AlH₃.NMe₃, AlH₃.NMe₂Et, AlH₃.NMeEt₂, AlH₃.NEt₃, AlH₃.tetramethylethylenediamine (TMEDA), AlH₃.dioxane, or a combination thereof.

The solvent may be water, tetrahydrofuran (THF), an alcohol-based solvent, an ether-based solvent, a sulfide-based solvent, a toluene-based solvent, a xylene-based solvent, a benzene-based solvent, an alkane-based solvent, an oxane-based solvent, an amine-based solvent, a polyol-based solvent, or a combination thereof.

The composition may include 50 to 99 wt % of the solvent, and 1 to 50 wt % of the metal precursor.

The composition may further include a solution stabilizer.

The solution stabilizer may be diketone, amino alcohol, polyamine, ethanol amine, diethanol amine, ethane thiol, propane thiol, butane thiol, pentane thiol, hexane thiol, heptane thiol, octane thiol, nonane thiol, decane thiol, undecane thiol, pentane, hexane, heptane, octane, nonane, or a combination thereof.

Here, a content of the solution stabilizer may be 1 to 50 parts by weight based on 100 parts by weight of the solvent and the metal precursor.

Yet another embodiment of the present invention provides a conductive fiber and/or fabric manufactured by the method as described above.

Sheet resistance of the conductive fiber and/or fabric may be 0.001 to 100 Ω/sq.

Electrical specific resistivity of the conductive fiber and/or fabric may be 1.0 to 100 μΩ·cm.

Yet another embodiment of the present invention provides a method for manufacturing a circuit board, the method including bonding the conductive fiber and/or fabric as described above.

In the bonding of the conductive fiber and/or fabric to the substrate, the conductive fiber and/or fabric and the substrate may be bonded to each other by using an adhesive.

In the bonding of the conductive fiber and/or fabric to the substrate, the conductive fiber and/or fabric may be placed on the substrate and then a pressure may be applied thereto, to thereby bond the conductive fiber and/or fabric and the substrate to each other.

In the bonding of the conductive fiber and/or fabric to the substrate, the conductive fiber and/or fabric may be placed on the substrate and heat may be applied thereto, to thereby bond the conductive fiber and/or fabric and the substrate to each other.

In the bonding of the conductive fiber and/or fabric to the substrate, the conductive fiber and/or fabric may be bonded to the substrate by needle-working or sewing.

In the bonding of the conductive fiber and/or fabric to the substrate, the conductive fiber may be directly applied to a fabric weaving procedure.

Yet another embodiment of the present invention provides a circuit board obtained by the method for manufacturing a circuit board as described above.

Yet another embodiment of the present invention provides an electromagnetic interference shielding material using the conductive fiber and/or fabric manufactured by the foregoing method.

Yet another embodiment of the present invention provides an electronic device using the conductive fiber and/or fabric manufactured by the foregoing method.

Yet another embodiment of the present invention provides building materials, mechanical materials, medical materials, and/or clothing materials including the conductive fiber and/or fabric manufactured by the foregoing method.

More specifically, a fiber and/or fabric-type electrode and a fiber and/or fabric-type electric circuit board having excellent accessibility, that are capable of being applied to various parts for vehicle, such as for impact detection and a heat generating sheet, interior and exterior building materials, such as illuminating paper, heating paper, and curtains for shielding electromagnetic interference, medical materials capable of sensing heart rates, sensing and maintaining body temperature, sensing and monitoring motion of a detected human body, and the like, and clothing materials with illuminating devices for the stage, accessories, and safety protection, as well as wearable electronics such as a wearable computer and a human body protecting device, can be manufactured.

According to an embodiment of the present invention, an effective method for manufacturing a conductive fiber and/or fabric can be provided and thus an electric circuit board having excellent accessibility can be manufactured. More specifically, a conductive fiber and/or fabric can be manufactured without damage thereof through a low-temperature process.

Further, according to an embodiment of the present invention, a fiber and/or fabric type of electrode and a fiber and/or fabric type of electric circuit board capable of having excellent accessibility and being applied to wearable electronic devices, such as a wearable computer, a human-protectable device, and the like, can be manufactured.

### BRIEF DESCRIPTION OF THE DRAWINGS

FIG. 1 shows general experimental images of a conductive fabric according to Example 1.

FIG. 2 shows electrical characteristic data of the conductive fabric according to Example 1.

FIG. 3 shows general experimental images of a conductive fabric according to Example 2.

FIG. 4 shows electrical characteristic data of the conductive fabric according to Example 2.

FIG. 5 shows an image illustrating that when electricity is supplied to an LED lamp connected to conductive yarns according to Example 3, the LED lamp is turned on.

FIG. 6 shows electrical characteristic data of the conductive yarn according to Example 3.

FIG. 7 shows an image illustrating that when electricity is supplied to an LED lamp connected to conductive yarns according to Example 4, the LED lamp is turned on.

FIG. 8 shows electrical characteristic data of the conductive yarn according to Example 4.

FIG. 9 shows a general image of a circuit manufactured by bonding conductive fabric and yarn onto a cotton fabric that does not conduct electricity through needlework.

FIG. 10 shows a general image illustrating a state when electricity is supplied to an LED lamp of a circuit constituted on a cotton fabric by using conductive fabrics and yarns.

FIG. 11 shows a graph illustrating sheet resistances of conductive papers manufactured according to example A-1 and example A-2 and general images illustrating states when electricity is supplied to LEDs connected to circuits constituted on the manufactured conductive papers.

### DETAILED DESCRIPTION OF THE EMBODIMENTS

Hereinafter, the present invention will be descried in detail with reference to embodiments thereof. However, these are given merely for illustration, and the present invention is not limited thereto. The present invention is defined based on the scopes of claims to be described later.

As used herein, for example, the term “C20” has the same meaning as “20 carbons”.

As used herein, the term “substitution”, unless separately defined, means that a substituent or at least one hydrogen of a compound is substituted with deuterium, a halogen, a hydroxy, a amino, a substituted or unsubstituted C1-C30 amine, a nitro, a substituted or unsubstituted C3-C40 silyl, a C1-C30 alkyl, a C1-C10 alkylsilyl, a C3-C30 cycloalkyl, a C6-C30 aryl, a C1-C20 alkoxy, a fluoro, a C1-C10 trifluoroalkyl such as trifluoromethyl, or a cyano.

In addition, two adjacent substituents of the substituted halogen, hydroxy, amino, substituted or unsubstituted C₁₋₂₀ amine, nitro, substituted or unsubstituted C3-C40 silyl, C1-C30 alkyl, C1-C10 alkylsilyl, C3-C30 cycloalkyl, C6-C30 aryl, C1-C20 alkoxy, fluoro, C1-C10 trifluoroalkyl such as trifluoromethyl, or cyano may be used to form a ring.

As used herein, the term “hetero”, unless separately defined, means that a single functional group contains 1 to 3 heteroatoms selected from the group consisting of N, O, S, and P, and carbon atoms as the remainder.

In the present specification, the alkyl may be a C1-C20 alkyl. More specifically, the alkyl may be a C1-C10 alkyl or a C1-C6 alkyl. For example, C1-C4 alkyl means that 1 to 4 carbon atoms are included in an alkyl chain, and means being selected from the group consisting of methyl, ethyl, propyl, iso-propyl, n-butyl, iso-butyl, sec-butyl, and t-butyl.

As a specific example, the alkyl means methyl, ethyl, propyl, iso-propyl, butyl, iso-butyl, t-butyl, pentyl, hexyl, cyclopropyl, cyclobutyl, cyclopentyl, cyclohexyl, or the like.

The term “aryl” means a substituent in which all elements of a cyclic substituent have p-orbitals, which form conjugation. The aryl includes a monocyclic or fused ring polycyclic (i.e., rings sharing adjacent carbon atom pairs) functional group.

The term “heteroaryl” means that an aryl contains 1 to 3 hetero atoms selected from the group consisting of N, O, S, and P, and carbon atoms as the remainder. When the heteroaryl is a fused ring, each ring may include 1 to 3 heteroatoms.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

According to an embodiment of the present invention, a method for manufacturing a conductive fiber and/or fabric is provided, the method including: preparing a composition including a solvent and a metal precursor; impregnating a fiber and/or fabric with the composition; and reducing or decomposing the metal precursor in the fiber and/or fabric impregnated with the composition into a metal to obtain a conductive fiber and/or fabric.

As a specific example, the reducing or decomposing of the metal precursor in the fiber and/or fabric impregnated with the composition into a metal to obtain a conductive fiber and/or fabric may mean that a compound such as AlH₃, which is a specific example of the metal precursor, is decomposed to form Al.

The fiber and/or fabric means a fiber and/or fabric usable in general clothing, and is not limited to particular kinds. In addition, the fabric may be textile such as cloth consisting of fibers, a non-woven fabric such as paper, or the like.

The metal precursor may be represented by Chemical Formula 1 and/or 2.

R¹ₓM_{w}R²_{z} [Chemical Formula 1]

[R¹_{y}A]ₓM_{w}R²_{z} [Chemical Formula 2]

Herein, in Chemical Formula 1 and Chemical Formula 2, A is at least one of VA-group elements or VIA-group elements; x is any one integer of 0 to 3; y is any one integer of 1 to 3; z is any one integer of 1 to 8; w is any one integer of 1 to 5; R¹ and R² are each independently H, a C₁-C₂₀ alkyl group, a C₂-C₂₀ alkenyl group, a C₂-C₂₀ alkynyl group, a C₃-C₁₂₀ cycloalkyl group, a C₄-C₁₂₀ cycloalkenyl group, a C₆-C₁₀₀ aryl group, or a C₇-C₁₀₀ aralkyl group; and M is aluminum (Al), lithium (Li), sodium (Na), potassium (K), rubidium (Rb), cesium (Cs), beryllium (Be), magnesium (Mg), calcium (Ca), strontium (Sr), barium (Ba), titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), gallium (Ga), indium (In), thallium (Tl), silicon (Si), germanium (Ge), tin (Sn), lead (Pb), phosphorous (P), arsenic (As), antimony (Sb), bismuth (Bi), or a combination thereof.

For example, when the metal precursor is AlH₃, M is Al, R¹ is H, x is 3, w is 1, z is 0, and R² is not present, based on Chemical Formula 1. For another example, when the metal precursor is AlH₃O(C₄H₉)₂, M is Al, R¹ is H, x is 3, R² is O(C₄H₉)₂, and z is θ1, based on Chemical Formula 1. In some cases, the number of materials corresponding to R² may be 1 or greater.

As another example, when the metal precursor is Cu₂(OH₂)₂(O₂C(CH₂)₄CH₃)₄, M is Cu, w is 2, R¹ is H₂O, x is 2, R² is OC(CH₂)₄CH₃, and z is 4, based on Chemical Formula 1.

More specifically, the metal precursor may be a metal hydride, a metal hydroxide, a metal sulfur oxide, a metal nitrate, a metal halide, a complex thereof, and a combination thereof. When the metal precursor has a structure as described above, a reduction or decomposition reaction may occur more effectively at the time of manufacturing a conductive fiber and/or fabric later.

More specifically, the metal precursor may be a type of metal inorganic salt, and a negative ion of the metal inorganic salt may be a hydroxide ion, an acetate ion, a propionate ion, an acetylacetonate ion, a 2,2,6,6-tetramethyl-3,5-heptanedionate ion, a methoxide ion, a sec-butoxide ion, a t-butoxide ion, an n-propoxide ion, an i-propoxide ion, an ethoxide ion, a phosphate ion, an alkylphosphonate ion, a nitrate ion, a perchlorate ion, a sulfate ion, an alkylsulfonate ion, a phenoxide ion, a bromide ion, an iodide ion, a chloride ion, a nitride ion, a nitrate ion, a sulfide ion, a sulfate ion, or a combination thereof.

In addition, a metal of the metal precursor may be aluminum (Al), lithium (Li), sodium (Na), potassium (K), rubidium (Rb), cesium (Cs), beryllium (Be), magnesium (Mg), calcium (Ca), strontium (Sr), barium (Ba), titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), gallium (Ga), indium (In), thallium (Tl), silicon (Si), germanium (Ge), tin (Sn), lead (Pb), phosphorus (P), arsenic (As), antimony (Sb), bismuth (Bi), or a combination thereof, and is not limited thereto as long as it is a conductive metal.

More specifically, the metal precursor may be AlH₃, OAlH₃(C₂H₅)₂, OAlH₃(C₃H₇)₂, OAlH₃(C₄H₉)₂, AlH₃.NMe₃, AlH₃.NMe₂Et, AlH₃.NMeEt₂, AlH₃.NEt₃, AlH₃.tetramethylethylenediamine (TMEDA), AlH₃.dioxane, or a combination thereof.

For another example, the metal precursor may be a metal chloride, a metal hydride, a metal hydroxide, a metal sulfide, a metal nitrate, a metal nitride, a metal halide, a metal alkyl compound, a metal aryl compound, a complex thereof, or a combination thereof.

As a more specific example, the metal precursor may be a compound in which organic and inorganic ligands are respectively or complexly linked to a metal hydride (MHₓ). Here, M, which is a metal, may be titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), mercury (Hg), aluminum (Al), gallium (Ga), germanium (Ge), indium (In), tin (Zn), antimony (Sb), thallium (Tl), lead (Pb), bismuth (Bi), lithium (Li), beryllium (Be), sodium (Na), magnesium (Mg), potassium (K), calcium (Ca), rubidium (Rb), strontium (Sr), cesium (Cs), barium (Ba), silicon (Si), or the like, and x is an integer of 1 to 7.

In addition, as a specific example, the metal precursor according to an embodiment of the present invention consists of a metal hydride, which is a core material of the metal precursor, or a compound in which various organic or inorganic ligands are linked to a metal hydride, independently or in a mixture.

More specifically, a core material of the metal precursor is metal hydride (MHx), and various organic or inorganic materials are linked to the core material to thereby constitute a more stable and effective aluminum metal precursor. Here, the “metal hydride” means a compound in which a metal and at least one hydrogen atom are directly linked to each other. More specifically, it may be MHₙYₘ₋ₙ, and here, Y is a halogen group element, —OR, or —R (herein, R is an alkyl, aryl, or aryl compound, or the like), n is an integer of 7 or less, and m is an integer of 1 to 7. M is a metal, and may be titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), mercury (Hg), aluminum (Al), gallium (Ga), germanium (Ge), indium (In), tin (Zn), antimony (Sb), thallium (Tl), lead (Pb), bismuth (Bi), lithium (Li), beryllium (Be), sodium (Na), magnesium (Mg), potassium (K), calcium (Ca), rubidium (Rb), strontium (Sr), cesium (Cs), barium (Ba), silicon (Si), or the like.

In addition, as another specific example, the metal precursor may be present such that one or two of amines, phosphines, ethers, sulfides, thiols, and/or other appropriate ligands are linked to the metal hydride to constitute a complex.

However, the present invention is not limited to the above-exemplified materials. For example, the metal precursor consists of one or more of the following materials: 1) a metal hydride, 2) a metal hydride with a C₁-C₂₀ alkyl linked thereto (isobutyl-metal hydride, triisobutyl-metal hydride, dimethyl-metal hydride, or the like), and 3) a metal hydride containing one or two ligands such as amines, phosphines, ethers, sulfides, thiols, and the like. A representative example of the complex may be a metal hydride complex containing a C₁-C₂₀ alkyl-containing amine having a low molecular weight, such as a trialkyl amine (trimethylamine alane, triethylamine alane, tripropylamine alane, dimethylethylamine alane, diethylmethylamine alane, or the like). However, the metal precursor is not limited to the above-exemplified materials.

For example, the metal hydride may form a complex together with a bidentate ligand, such as ethylene amine, tetramethyl hydrazine, 2,2-bipyridine, 1,2-bis(diphenyl phosphino) ethane, 1,3-bis(diphenyl phosphino)propane, or the like, to become a metal precursor.

This metal precursor may be represented by [R¹ᵥA]ₓMR²_{z}.

Here, A may be a VA-group element such as N, P, As, or Sb or a VIA-group element such as O, S, Se, or Te, x may be 1 or 2, y may be 2 or 3, and z may be an integer of 1 to 8. R¹ and R² may each independently be H, a C₁-C₂₀ alkyl, a C₂-C₂₀ alkenyl, a C₂-C₂₀ alkynyl, a C₃-C₁₂₀ cycloalkyl, a C₄-C₁₂₀ cycloalkenyl, a C₆-C₁₀₀ aryl, or a C₇-C₁₀₀ aralkyl. In general, A is the VIA-group element when y is 2, and the VA group element when y is 3.

In addition, a metal hydride and an amine complex may also be used as a metal precursor, and a general type thereof may be represented as below. [R¹ᵥN]ₓMR²_{z}. Here, R¹ and R² may each independently be H, a C₁-C₂₀ alkyl, a C₂-C₂₀ alkenyl, a C₂-C₂₀ alkynyl, a C₃-C₁₂₀ cycloalkyl, a C₄-C₁₂₀ cycloalkenyl, a C₆-C₁₀₀ aryl, or a C₇-C₁₀₀ aralkyl. In addition, the R group may be linked to an N atom to form an aliphatic or aromatic cyclic ring. As for the metal hydride complex having an amine group, specific examples of the amine group may be a monoalkylamine, a dialkylamine, and trialkylamine complexes, piperidine or pyrrolidone complexes, and the like.

An example of the metal hydride and amine complex may be a metal hydride trialkylamine complex, and the trialkylamine may be trimethylamine, triethylamine, tri-n-propylamine, triisopropylamine, methyldiethylamine, dimethylethylamine, n-propyldimethylamine, or isopropyldiethylamine.

A representative example of the aluminum metal precursor complex containing an amine may be trimethylamine alane, triethylamine alane, dimethylethylamine alane, diethylmethylamine alane, or a mixture thereof. Another example of the metal precursor may be a complex of a metal hydride and two amine ligands and/or one phosphine ligand. A general form thereof may be, for example, [R¹₃A]₂MR²_{z}. Here, A may independently be N or P, z may be an integer of 1 to 8, and R¹ and R² may each independently be H, a C₁-C₂₀ alkyl, a C₂-C₂₀ alkenyl, a C₂-C₂₀ alkynyl, a C₃-C₁₂₀ cycloalkyl, a C₄-C₁₂₀ cycloalkenyl, a C₆-C₁₀₀ aryl, or a C₇-C₁₀₀ aralkyl. The amine ligand may be an amine compound as described above.

The form of the phosphine ligand may be represented by PR¹₃. Here, R¹ may be a monoalkyl phosphine, a dialkyl phosphine, or a trialkyl phosphine. A specific example of the trialkyl phosphine may be trimethylphosphine, triethylphosphine, tri-t-butylphosphine, triphenylphosphine, triisopropylphosphine, tricyclohexylphosphine, or the like. A representative example of the aluminum metal precursor having this structure may be H₃Al{N(CH₃)₃}{P[C(CH₃)₃]}.

In addition, the metal precursor may be present in a form in which it contains a metal hydride and an ether and/or other ligands, and a general form thereof may be R²₃M(AR¹₃)(OR³₂) or R²₃A(OR³₂). Here, the ligand represented by AR¹₃ may be the foregoing amine or phosphine ligand, and the ligand represented by OR³₂ may be an ether ligand. The R³ group of the ether ligand may independently be H, a C₁-C₂₀ alkyl, a C₂-C₂₀ alkenyl, a C₂-C₂₀ alkynyl, a C₃-C₁₂₀ cycloalkyl, a C₄-C₁₂₀ cycloalkenyl, a C₆-C₁₀₀ aryl, or a C₇-C₁₀₀ aralkyl. The two R³ groups containing oxygen atoms are C₁-C₂₀ alkyls. Here, an appropriate example of the ether ligand may be diethylether, di-n-propylether, di-n-butylether, di-isopropylether, di-t-butylether, methyl-butylether, n-propyl-n-butylether, methyl-t-butylether, ethyl-t-butylether, tetrahydrofuran, or a mixture thereof.

A representative example of the aluminum metal precursor containing this ligand may be H₃M{N(CH₃)₃}{O(CH₂CH₃)₂}. Here, M is a metal, and may be titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), mercury (Hg), aluminum (Al), gallium (Ga), germanium (Ge), indium (In), tin (Zn), antimony (Sb), thallium (Tl), lead (Pb), bismuth (Bi), lithium (Li), beryllium (Be), sodium (Na), magnesium (Mg), potassium (K), calcium (Ca), rubidium (Rb), strontium (Sr), cesium (Cs), barium (Ba), silicon (Si), or the like.

The solvent may be water, tetrahydrofuran (THF), an alcohol-based solvent, an ether-based solvent, a sulfide-based solvent, a toluene-based solvent, a xylene-based solvent, a benzene-based solvent (e.g., benzene, 1,3,5-trinitromethylbenzene, or the like), an alkane-based solvent (e.g., CₙH₂ₙ₊₂, C₅H₁₂, C₆H₁₄, C₇H₁₆, C₈H₁₈, or the like), an oxane solvent, an amine solvent, a polyol-based solvent, or a combination thereof, and is not limited thereto. However, the solvent may be selectively used depending on the kind of the metal precursor.

The composition may include 50 to 99 wt % of the solvent and 1 to 50 wt % of the metal precursor. This range may be appropriate for effectively impregnating the fiber and/or fabric with the composition.

The composition may further include a solution stabilizer.

The solution stabilizer may be diketone, amino alcohol, polyamine, ethanol amine, diethanol amine, ethane thiol, propane thiol, butane thiol, pentane thiol, hexane thiol, heptane thiol, octane thiol, nonane thiol, decane thiol, undecane thiol, or a combination thereof.

In addition, as the solution stabilizer, an alkane-based stabilizer may be used. Specifically, examples thereof may be pentane, hexane, heptane, octane, nonane, and the like.

The content of the solution stabilizer may be 1 to 50 parts by weight or 1 to 20 parts by weight based on 100 parts by weight of the solvent and metal precursor. This range may be appropriate for impregnating the fabric and/or fabric with the composition.

The impregnating of the fiber and/or fabric with the composition may be performed by a general method.

For example, the fiber and/or fabric may be put in the composition, so that the fiber and/or fabric can be sufficiently impregnated with the composition. The impregnating of the fiber and/or fabric is not limited thereto as long as features of the general fiber and/or fabric are not damaged.

The metal precursor in the fiber and/or fabric impregnated with the composition is reduced into a metal, thereby obtaining a conductive fiber and/or fabric.

The reducing or decomposing of the metal precursor in the fiber and/or fabric impregnated with the composition into the metal to obtain the conductive fiber and/or fabric may be performed while the fiber and/or fabric impregnated with the composition is maintained at room temperature for a predetermined time. That is, the conductive fiber and/or fabric can be obtained without a separate heat treatment procedure.

More specifically, the fiber and/or fabric may be immersed in the composition, and then maintained at room temperature for a predetermined time.

Alternatively, the reducing or decomposing of the metal precursor in the fiber and/or fabric impregnated with the composition into the metal to obtain the conductive fiber and/or fabric may be performed while the fiber and/or fabric impregnated with the composition is subjected to heat treatment. Here, the temperature for heat treatment may have a low-temperature range within which the fiber and/or fabric is not damaged. As a specific example, the temperature may be 150° C. or lower.

In addition, for the heat treatment, the fiber and/or fabric impregnated with the composition may be subjected to heat treatment in an oven or on a hot plate. Alternatively, heating may be performed while the fiber and/or fabric are immersed in the composition.

In addition, the fiber and/or fabric may be treated with a catalyst or a reducing agent, before the fiber and/or fabric is impregnated with the composition.

Examples of the catalyst usable herein may be 4B and 5B group metals, or a halogenated compound or alkoxide compound with the metal, such as titanium isopropoxide (Ti(O-i-Pr)₄), titanium chloride (TiCl₄), a Lindlar catalyst, or the like. Also, examples thereof may be a material in which a metal, such as Pt, Pd, Co, or W, is also present in an independent manner or a compound type. Examples of the reducing agent may be lithium aluminum hydride (LiAlH₄), hydrogen (H), a sodium-mercury amalgam (Na(Hg)), super-hydride (NaBH₄), Sn²⁺-containing compounds (SnCl₂, etc.), SO₃²⁻-containing compounds (sulfites: Na₂SO₃, NaHSO₃, KHSO₃, etc.), hydrazine (N₂H₄), di-isobutyl aluminum hydride (DIBAH), oxalic acid (C₂H₂O₄), formic acid (HCOOH), ascorbic acid (C₆H₈O₆), phosphate (PO₃³⁻), and hypophosphite (H₂PO²⁻). Also, examples thereof may be phosphorous acid (H₃PO₃), dithiothreitol (DDT, C₄H₁₀O₂S₂), and Fe²⁺ ion-containing compounds (FeSO₄, etc.).

As a specific example for the reducing agent, sodium hydroxide (NaOH), lithium borohydride (LiBH₄), sodium borohydride (NaBH₄), potassium borohydride (KBH₄), lithium aluminum hydride (LiAlH₄), sodium aluminum hydride (NaAlH₄), potassium aluminum hydride (KAlH₄), and the like may be used independently or as a mixture.

That is, in the case where the metal precursor is reducible into a metal at a room temperature range without external supply of energy, the conductive fiber and/or fabric can be obtained by maintaining a non-conductive fiber and/or fabric in the room-temperature metal precursor composition for a predetermined time.

However, in the case where some external energy is needed depending on the kind of the metal precursor, heat treatment or a catalyst may be employed.

In the present specification, the room temperature means a state in which external energy is not particularly supplied, and may be changed depending on the region, time, or the like.

According to another embodiment of the present invention, a conductive fiber and/or fabric manufactured by the method as described above is provided.

The conductive fiber and/or fabric may have sheet resistance of 0.001 to 100 Ω/sq. In addition, the conductive fiber and/or fabric may have specific electrical resistivity of 10 to 100 μΩ·cm. More specifically, it may be 1.5 to 100 μΩ·cm.

This range is sufficient to use the conductive and/or fiber as a substrate and an electrode in the electrical and/or electronic field.

According to still another embodiment of the present invention, a method for manufacturing a circuit board is provided, the method including bonding the foregoing conductive fiber and/or fabric to a substrate.

The bonding of the conductive fiber and/or fabric to the substrate may be performed such that the conductive fiber and/or fabric is bonded onto the substrate by using an adhesive. The adhesive usable herein is not particularly limited as long as it can be used in general electrical and electronic device fields.

Alternatively, the bonding of the conductive fiber and/or fabric to the substrate may be performed such that, after the conductive fiber and/or fabric is placed on the substrate, a pressure is applied thereto, thereby bonding them. Alternatively, the bonding of the conductive fiber and/or fabric to the substrate may be performed such that, after the conductive fiber and/or fabric is placed on the substrate, heat is applied thereto, thereby bonding them.

The heat and pressure conditions may be controlled depending on the kind of substrate and required characteristics.

Alternatively, the bonding of the conductive fiber and/or fabric to the substrate may be performed such that the conductive fiber and/or fabric are bonded to the substrate through needlework or sewing. This method employs features of the fiber and/or fabric, and may be applied in various fields without being limited by the kind of substrate.

Alternatively, the bonding of the conductive fiber and/or fabric to the substrate may be performed such that the conductive fiber is used to directly weave the fabric. This method employs features of the fiber and/or fabric, and may be applied in various fields without being limited by the kind of substrate.

According to still another embodiment of the present invention, a circuit board manufactured by the method for manufacturing a circuit board as described above is provided. The circuit board may be an electronic circuit board, an electric circuit board, or the like.

According to still another embodiment of the present invention, electromagnetic interference shielding materials using the conductive fiber and/or fabric manufactured by the foregoing embodiment of the present invention are provided. This electromagnetic interference shielding has been widely known in the art, and thus descriptions thereof will be omitted. If one embodiment of the present invention may be used for a particular constitution, the use range thereof is not limited.

According to still another embodiment of the present invention, mechanical and electronic devices using the conductive fiber and/or fabric manufactured by the foregoing embodiment of the present invention are provided. A specific example of the electronic device may have various ranges of a wearable computer, an RFID, and the like, and thus is not limited to special mechanical and electronic devices.

According to still another embodiment of the present invention, a part for a vehicle using the conductive fiber and/or fabric manufactured by the foregoing embodiment of the present invention is provided. A specific example of the part for a vehicle may have various ranges of an impact sensing device, a heating sheet, a moisture-removing and heating glass, and the like, and thus is not particularly limited to a particular part for a vehicle.

According to still another embodiment of the present invention, interior and exterior building materials, using the conductive fiber and/or fabric manufactured by the foregoing embodiment of the present invention, are provided. Specific examples of the interior and exterior building materials may have various ranges of illuminating wallpaper, heating paper, an electromagnetic interference curtain, an ultraviolet shielding curtain, and the like, and thus are not limited to particular interior and exterior building materials.

According to still another embodiment of the present invention, mechanical materials using the conductive fiber and/or fabric manufactured by the foregoing embodiment of the present invention are provided. Specific examples of the medical materials may have various ranges of a heartbeat sensing material, a body temperature sensing and maintaining material, a human body motion sensing and monitoring material, and the like, and are not limited to particular medical materials.

According to still another embodiment of the present invention, clothing materials for the stage, accessories, and safety protection, using the conductive fiber and/or fabric manufactured by the foregoing embodiment of the present invention, are provided. Specific examples of the clothing materials for the stage, accessories, and safety protection may be a helmet with an illuminating device, a safety jacket, safety shoes, and the like, and may have various ranges of shirts, jackets, pants, shoes, hats, and bags, with glossy illuminating devices, for the stage and accessories, and are not limited to particular clothing materials.

Hereinafter, specific examples of the present invention will be described. However, the examples below are merely for specifically illustrating and explaining the specification, and thus the present invention is not limited thereto.

### Example 1

### Preparation of Conductive Fabric

Preparation of Metal Precursor Ink Composition

AlCl₃ and LiAlH₄ were mixed at a molar ratio of 1:3 in dibutylether, and then heated and stirred at 70° C. for 1 hour. The solution that was heated and stirred for 1 hour was subjected to filtration to filter out byproducts, thereby obtaining a metal precursor ink composition as a clean solution.

The composition consists of about 20 wt % of an aluminum precursor and about 80 wt % of dibutylether.

However, at the time of preparing the aluminum precursor ink composition, AlCl₃ and LiAlH₄ were generally used at a molar ratio of 1:3, but may be used at a molar ratio of 1:5 for inducing a complete reaction by using an excessive amount of LiAlH₄.

Preparation of Conductive Fiber and/or Fabric

The aluminum precursor ink composition prepared by the above reaction easily decomposes at room temperature, resulting in Al. Therefore, the fabric formed of cotton was immersed and maintained in the aluminum precursor ink for about 1 day, thereby obtaining a conductive fabric.

### Example 2

### Preparation of Conductive Fabric

In order to manufacture a conductive fiber and/or fabric more rapidly, a fabric formed of cotton was exposed to a space in which a vapor state of titanium isopropoxide (Ti(O-i-Pr)₄) was produced and supplied, and was then maintained at room temperature for about 1 hour while being immersed in the aluminum precursor ink composition.

### Experimental Example 1

### Evaluation on Electrical Conductivity of Conductive Fabric

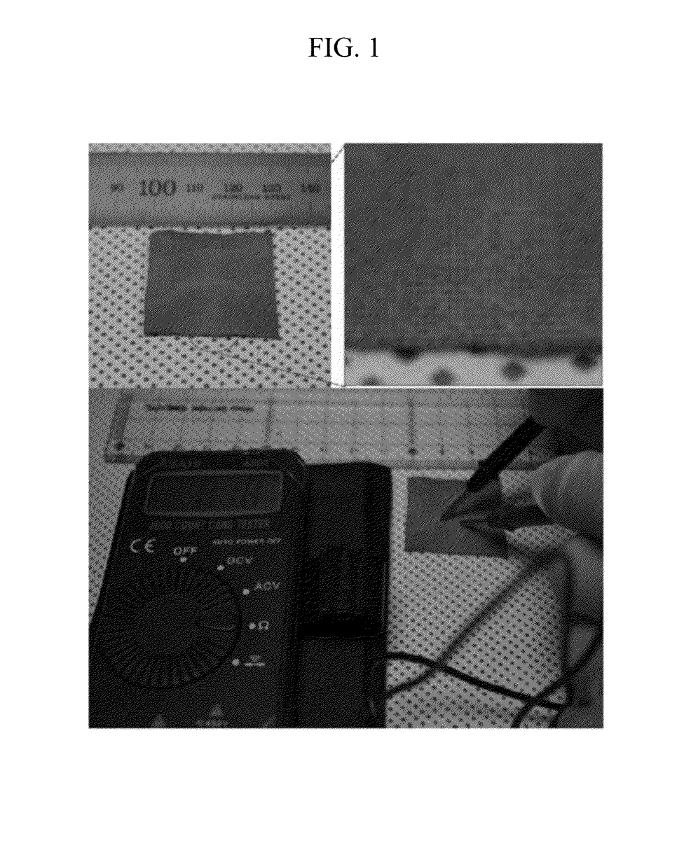

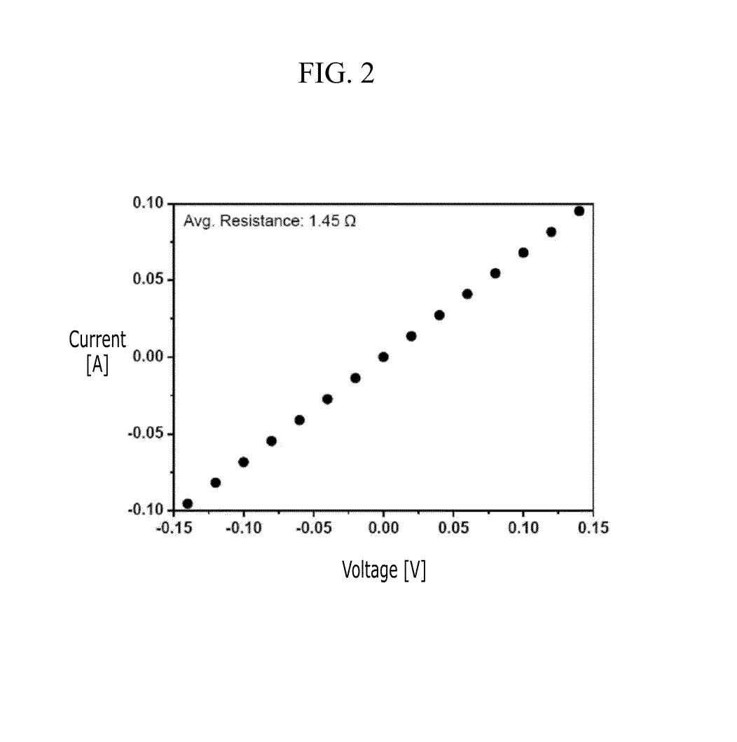

FIG. 1 shows general experimental images of a conductive fabric according to Example 1, and FIG. 2 shows electrical characteristic data of the conductive fabric according to Example 1.

The results can show that a white background of cotton fabric was coated with aluminum and thus changed into a dark gray fabric, and can confirm that it had electrical resistance of about 1.45Ω and thus excellent electrical conductivity.

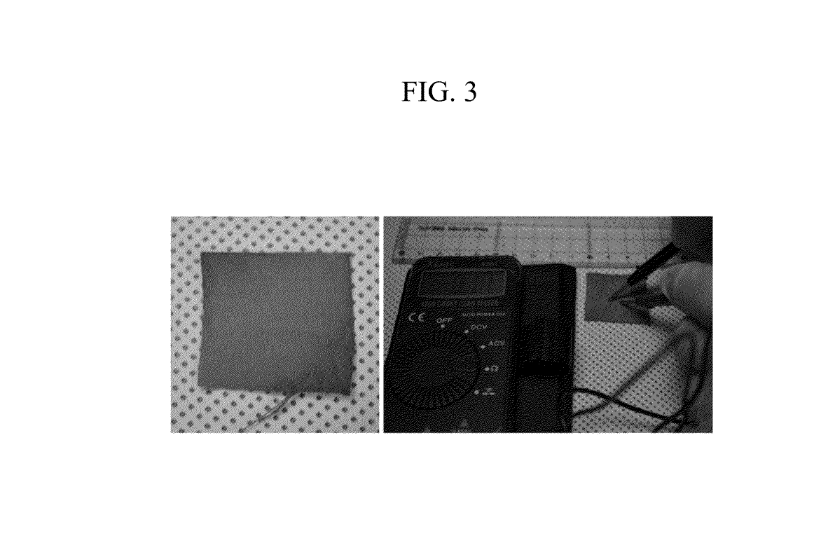

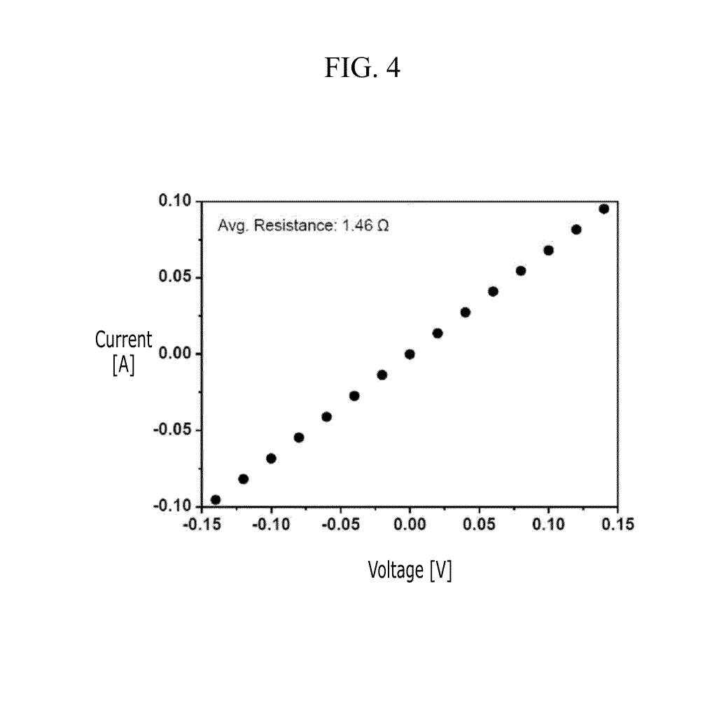

FIG. 3 shows general experimental images of a conductive fabric according to Example 2, and FIG. 4 shows electrical characteristic data of the conductive fabric according to Example 2

The result can show that a white background of a cotton fabric was coated with aluminum and thus changed into a dark gray fabric, like in the conductive fabric manufactured without using a catalyst, and can confirm that it had an electrical resistance of about 1.46Ω and thus excellent electrical conductivity.

### Example 3

### Preparation of Conductive Yarn

A conductive yarn was manufactured by using the same method as Example 1, except that a yarn formed of cotton was used instead of the fabric formed of cotton.

### Example 4

### Preparation of Conductive Yarn

A conductive yarn was manufactured by using the same method as Example 2, except that a yarn formed of cotton was used instead of the fabric formed of cotton.

### Experimental Example 2

### Evaluation of Electrical Conductivity of Conductive Yarn

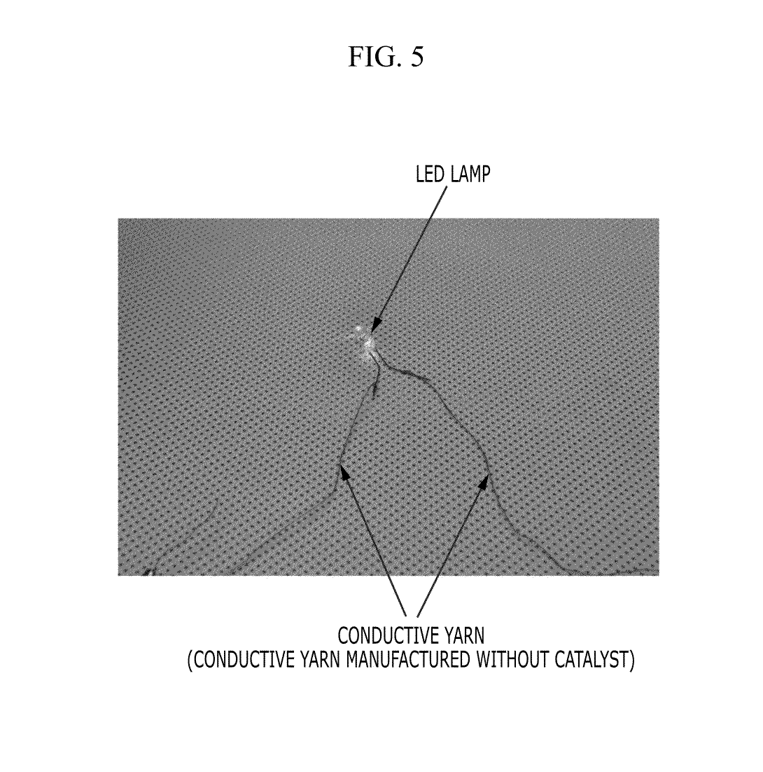

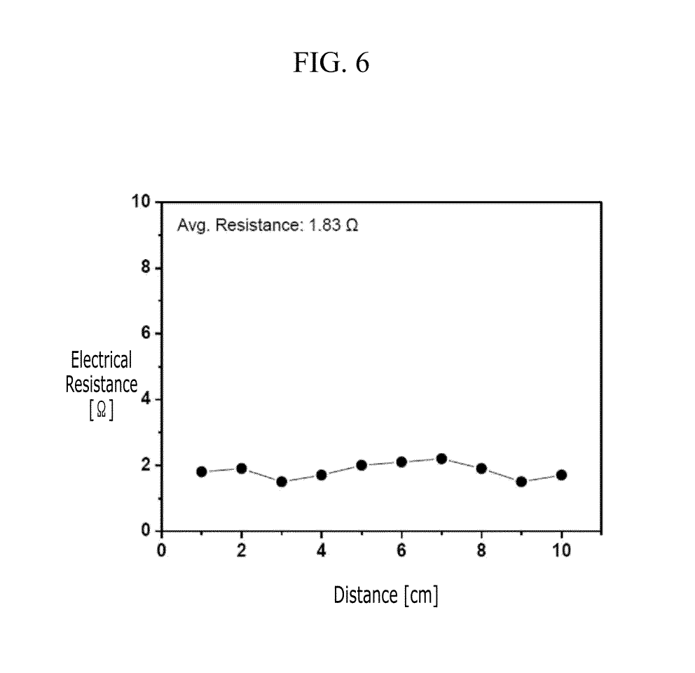

FIG. 5 shows an image illustrating that when electricity is supplied to an LED lamp connected to conductive yarns according to Example 3, the LED lamp is turned on, and FIG. 6 shows electrical characteristic data of the conductive yarn according to Example 3.

The results can show that a white background of cotton yarn was coated with aluminum and thus changed into a dark gray yarn, and can confirm that it had an electrical resistance of about 1.8Ω and thus excellent electrical conductivity.

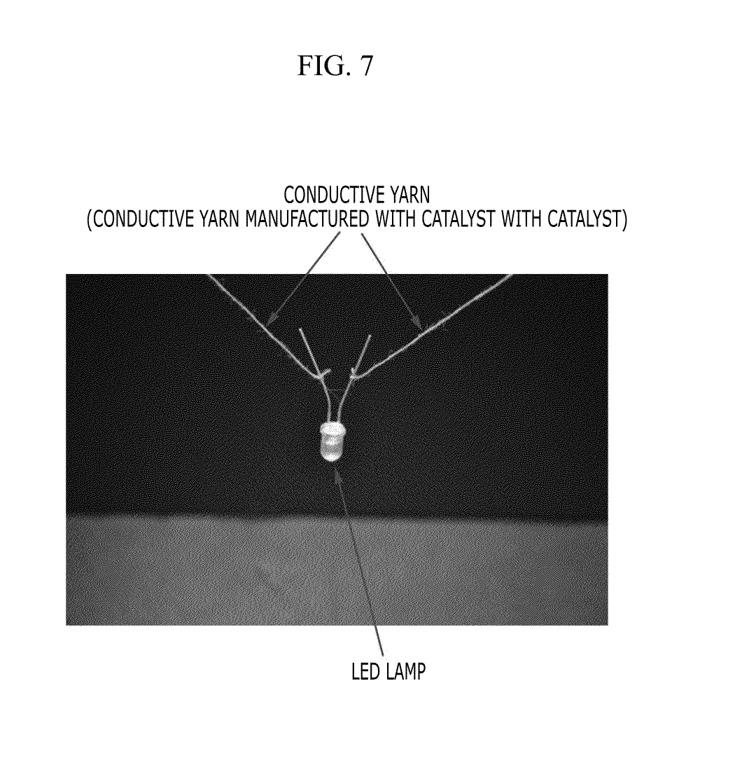

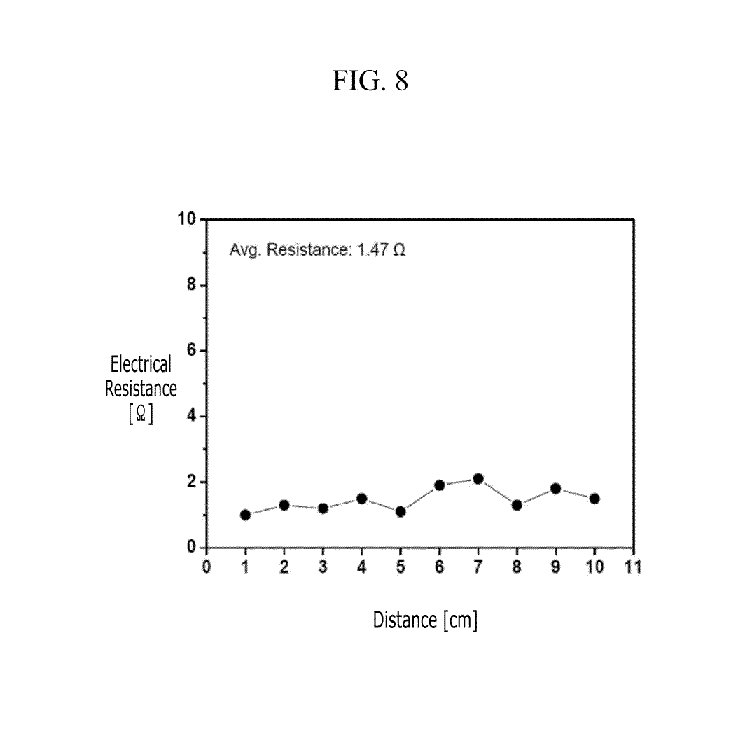

FIG. 7 shows an image illustrating that when electricity is supplied to an LED lamp connected to conductive yarns according to Example 4, the LED lamp is turned on, and FIG. 8 shows data on electrical characteristics of the conductive yarn according to Example 4.

The result can show that a white background of cotton yarn was coated with aluminum and thus changed into a dark gray yarn, like in the conductive yarn manufactured without using a catalyst, and can confirm that it had an electrical resistance of about 1.5Ω and thus excellent electrical conductivity.

### Experimental Example 3

### Design of Circuit using Conductive Fabric and Conductive Yarn

The fabric and yarn manufactured through Examples 2 and 4 were used to constitute an electric circuit on a non-conductive fabric, and electrical characteristics thereof were investigated.

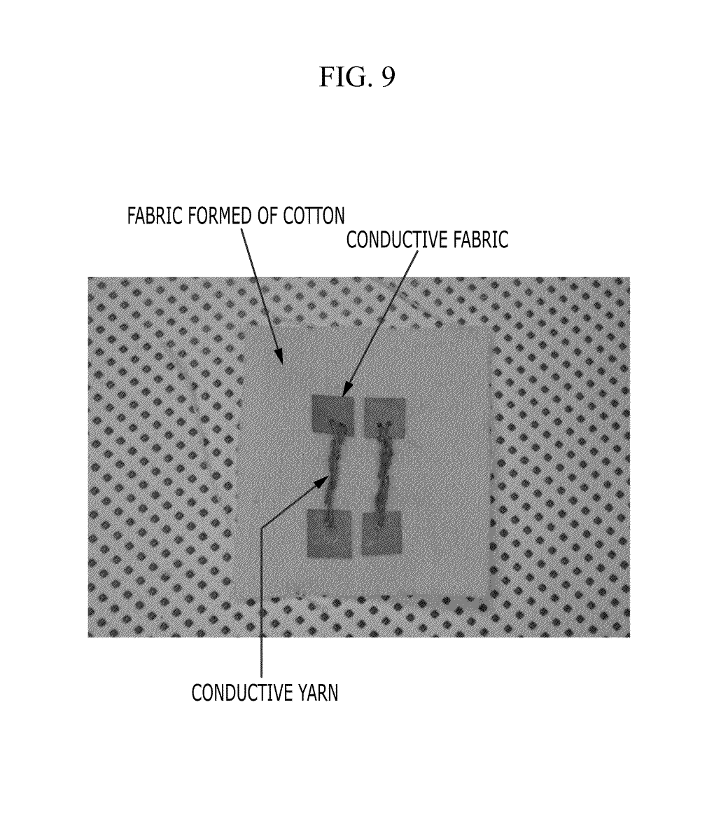

The conductive fabric with 0.5 cm×0.5 cm length and breadth and the conductive yarn were used to constitute an electric circuit on a general cotton fabric by using needlework, as shown in FIG. 9, and then an LED lamp was laid thereon. Then, electrical characteristics thereof were investigated.

FIG. 9 shows a general image of a circuit manufactured by bonding conductive fabric and yarn onto a cotton fabric that does not conduct electricity through needlework.

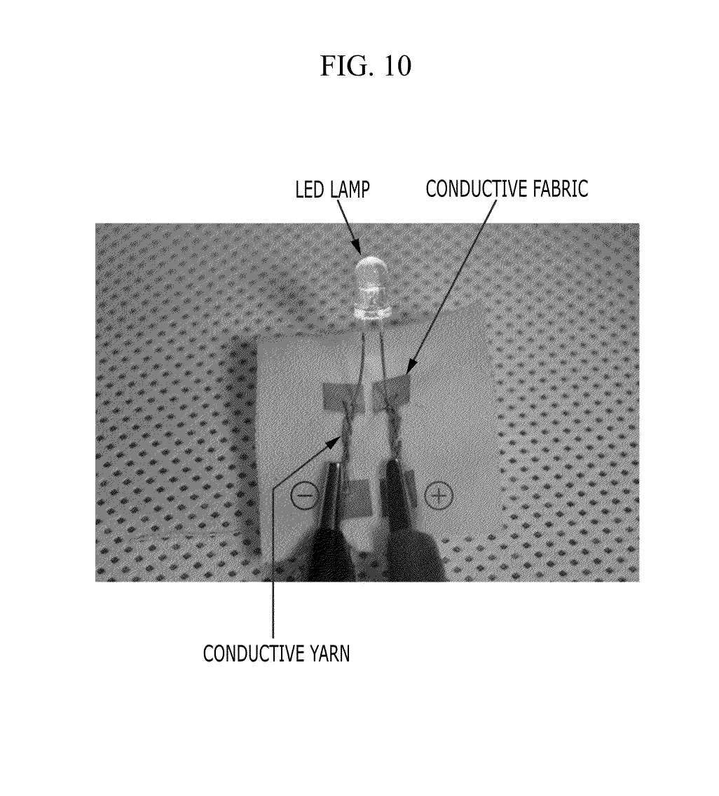

FIG. 10 shows a general image illustrating a state when electricity is supplied to an LED lamp of a circuit constituted on a cotton fabric by using conductive fabrics and yarns.

It may be confirmed that, when electricity was not supplied, the LED lamp was not turned on, but when about 3 volts of electricity was supplied, the LED lamp installed to the electric circuit composed of the conductive fiber and/or fabric was turned on.

### Example A-1

A conductive paper was manufactured by using the same method as Example 1, except that paper was used instead of the fabric formed of cotton.

### Example A-2

A conductive paper was manufactured by using the same method as Example 2, except that paper was used instead of the fabric formed of cotton.

### Experimental Example A-1

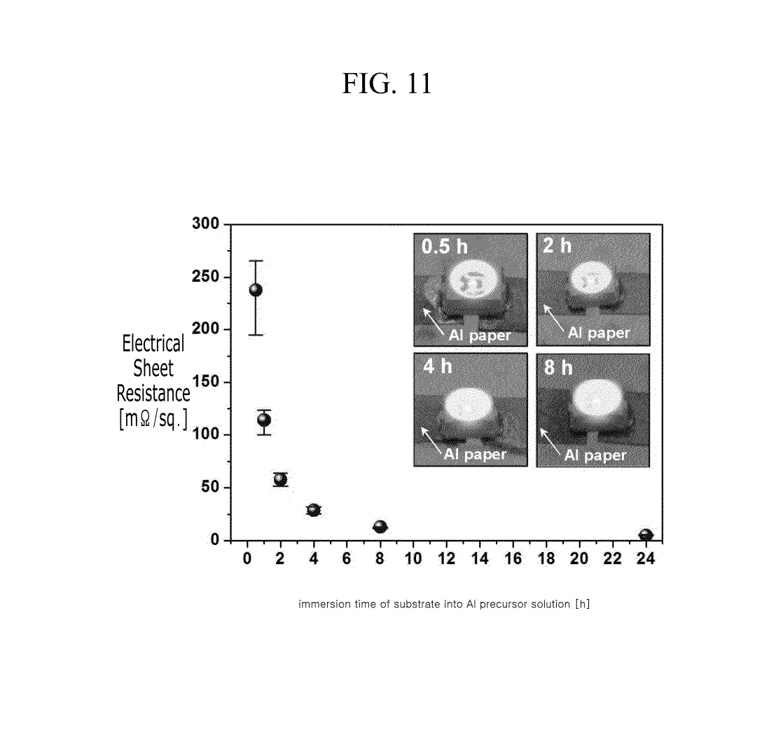

The sheet resistance of each of the papers manufactured through Examples A-1 and A-2 were measured, and the paper was used to form wires and an LED lamp was connected thereto. Then, it was directly investigated whether the paper was electrically conductive. FIG. 11 shows a graph illustrating sheet resistances of conductive papers manufactured by the amount of time the paper was immersed in the aluminum precursor solution. The images separately indicated in the graph show that when the papers manufactured by process times are used to constitute circuits, to which LED lamps were respectively connected, and then a voltage of about 3 V was applied thereto, the LED lamps were well turned on.

The present invention is not limited to the embodiments but may be implemented into different forms, and those skilled in the art will understand that the present invention may be implemented in alternative embodiments without changing technical spirits and necessary characteristics of the present invention. Accordingly, the embodiments described herein are provided by way of example only and should not be construed as being limiting.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method for manufacturing a conductive fiber and/or fabric, the method comprising:
preparing a composition comprising a solvent and a metal precursor;
impregnating a fiber and/or fabric with the composition; and
reducing or decomposing the metal precursor in the fiber and/or fabric impregnated with the composition into a metal to obtain a conductive fiber and/or fabric,
wherein the composition includes 50 to 99 wt % of the solvent and 1 to 50 wt % of the metal precursor.

2. The method of claim 1, wherein in the reducing or decomposing of the metal precursor in the fiber and/or fabric impregnated with the composition into the metal to obtain the conductive fiber and/or fabric, the fiber and/or fabric impregnated with the composition is maintained at room temperature for a predetermined time.

3. The method of claim 1, wherein in the reducing or decomposing of the metal precursor in the fiber and/or fabric impregnated with the composition into the metal to obtain the conductive fiber and/or fabric, the fiber and/or fabric impregnated with the composition is subjected to heat treatment.

4. The method of claim 3, wherein the heat treatment is performed at a temperature of 150° C. or lower.

5. The method of claim 1, further comprising, before the impregnating of the fiber and/or fabric with the composition, treating the fiber and/or fabric with a catalyst or a reducing agent.

6. The method of claim 1, wherein the metal precursor is a metal chloride, a metal hydride, a metal hydroxide, a metal sulfide, a metal nitrate, a metal nitride, a metal halide, a metal alkyl compound, a metal aryl compound, a complex thereof, or a combination thereof.

7. The method of claim 1, wherein the metal precursor is a compound in which organic or inorganic ligands are independently or complexly linked to a metal hydride.

8. The method of claim 7, wherein the organic and inorganic ligands are each independently selected from amines, phosphines, ethers, sulfides, thiols, and combinations thereof.

9. The method of claim 1, wherein the metal precursor is represented by Chemical Formula 1 and/or Chemical Formula 2 below:
R¹ₓM_{w}R²_{z} [Chemical Formula 1]
[R¹_{y}A]ₓM_{w}R²_{z} [Chemical Formula 2]
wherein in Chemical Formula 1 and Chemical Formula 2,
A is at least one of VA-group elements or VIA-group elements;
x is any one integer of 0 to 3;
y is any one integer of 1 to 3;
z is any one integer of 1 to 8;
w is any one integer of 1 to 5;
R¹ and R² each are independently H, a C₁-C₂₀ alkyl, a C₂-C₂₀ alkenyl, a C₂-C₂₀ alkynyl, a C₃-C₁₂₀ cycloalkyl, a C₄-C₁₂₀ cycloalkenyl, a C₆-C₁₀₀ aryl, or a C₇-C₁₀₀ aralkyl; and
M is aluminum (Al), lithium (Li), sodium (Na), potassium (K), rubidium (Rb), cesium (Cs), beryllium (Be), magnesium (Mg), calcium (Ca), strontium (Sr), barium (Ba), titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), gallium (Ga), indium (In), thallium (Tl), silicon (Si), germanium (Ge), tin (Sn), lead (Pb), phosphor (P), arsenic (As), antimony (Sb), bismuth (Bi), or a combination thereof.

10. The method of claim 1, wherein the metal precursor is a type of metal inorganic salt, a negative ion of the metal inorganic salt being a hydroxide ion, an acetate ion, a propionate ion, an acetylacetonate ion, a 2,2,6,6-tetramethyl-3,5-heptanedionate ion, a methoxide ion, a sec-butoxide ion, a t-butoxide ion, an n-propoxide ion, an i-propoxide ion, an ethoxide ion, a phosphate ion, an alkylphosphate ion, a nitrate ion, a perchlorate ion, a sulfate ion, an alkylsulfonate ion, a phenoxide ion, a bromide ion, an iodide ion, a chloride ion, a nitride ion, a nitrate ion, a sulfide ion, a sulfate ion, or a combination thereof.

11. The method of claim 1, wherein the metal precursor is AlH₃, OAlH₃(C₂H₅)₂, OAlH₃(C₃H₇)₂, OAlH₃(C₄H₉)₂, AlH₃.NMe₃, AlH₃.NMe₂Et, AlH₃.NMeEt₂, AlH₃.NEt₃, AlH₃.tetramethylethylenediamine (TMEDA), AlH₃.dioxane, or a combination thereof.

12. The method of claim 1, wherein the solvent is water, tetrahydrofuran (THF), an alcohol-based solvent, an ether-based solvent, a sulfide-based solvent, a toluene-based solvent, a xylene-based solvent, a benzene-based solvent, an alkane-based solvent, an oxane-based solvent, an amine-based solvent, a polyol-based solvent, or a combination thereof.

13. The method of claim 1, wherein the composition further comprises a solution stabilizer.

14. The method of claim 13, wherein the solution stabilizer is diketone, amino alcohol, polyamine, ethanol amine, diethanol amine, ethane thiol, propane thiol, butane thiol, pentane thiol, hexane thiol, heptane thiol, octane thiol, nonane thiol, decane thiol, undecane thiol, pentane, hexane, heptane, octane, nonane, or a combination thereof.

15. The method of claim 13, wherein a content of the solution stabilizer is 1 to 50 parts by weight based on 100 parts by weight of the solvent and the metal precursor.

16. The method of claim 1, wherein a sheet resistance of the conductive fiber and/or fabric is 0.001 to 100 Ω/sq.

17. The method of claim 1, wherein an electrical specific resistivity of the conductive fiber and/or fabric is 1.0 to 100 μΩ·cm.

18. A method for manufacturing a circuit board, the method comprising bonding the conductive fiber and/or fabric of claim 1 to a substrate.

19. The method of claim 18, wherein in the bonding of the conductive fiber and/or fabric to the substrate, the conductive fiber and/or fabric and the substrate are bonded to each other by using an adhesive.

20. The method of claim 18, wherein in the bonding of the conductive fiber and/or fabric to the substrate, the conductive fiber and/or fabric is placed on the substrate and then a pressure is applied thereto, to thereby bond the conductive fiber and/or fabric and the substrate to each other.

21. The method of claim 18, wherein in the bonding of the conductive fiber and/or fabric to the substrate, the conductive fiber and/or fabric is placed on the substrate and heat is applied thereto, to thereby bond the conductive fiber and/or fabric and the substrate to each other.

22. The method of claim 18, wherein in the bonding of the conductive fiber and/or fabric to the substrate, the conductive fiber and/or fabric is bonded to the substrate by needle-working or sewing.

23. The method of claim 18, wherein in the bonding of the conductive fiber and/or fabric to the substrate, the conductive fiber is directly applied to a fabric weaving procedure.
